(19) United States
(12) Patent Application Publication
(10) Pub. No.: US 2017/0257959 A1
(43) Pub. Date: Sep. 7, 2017

(54) ELECTRONIC CONTROL APPARATUS

(71) Applicant: FUJITSU TEN LIMITED, Kobe-shi (JP)

(72) Inventor: Takashi OGITANI, Kobe-shi (JP)

(73) Assignee: FUJITSU TEN LIMITED, Kobe-shi (JP)

(21) Appl. No.: 15/447,868

(22) Filed: Mar. 2, 2017

(30) Foreign Application Priority Data
Mar. 7, 2016 (JP) 2016-043127

(51) Int. Cl. H05K 5/00; H05K 7/14; H01R 43/20; H05K 5/02; H01R 13/516; H01R 12/71

(52) U.S. Cl. CPC H05K 5/0026; H01R 13/516; H01R 12/716; H01R 43/205; H05K 5/0017; H05K 5/0239; H05K 7/1418

(57) ABSTRACT

An electronic control apparatus includes a connector cover that: closes a first aperture; and has a second aperture through which a first side of a connector extends. The connector cover includes a covering wall that covers at least a second side of the connector that faces a second direction. Thus, since the connector is covered by the covering wall, it is possible to prevent a foreign object, dust, etc. from entering the case.

### BACKGROUND OF THE INVENTION

Field of the Invention

The invention relates to a technology for a dust prevention structure that prevents a foreign object from entering an electronic control apparatus.

Description of the Background Art

Conventionally, a large number of electronic control apparatuses that control a remote engine starter system, airbags, etc. have been mounted on a vehicle. Each electronic control apparatus includes connectors, and is connected, via the connector, to an object that the electronic control apparatus controls. A small aperture is generated between the connector and a case in a location in which the connector is installed in the electronic control apparatus. Thus, there is a possibility that an electronic circuit board inside the electronic control apparatus may be adversely affected by a small metal debris, another foreign object and/or dust entering the electronic control apparatus from the aperture.

Therefore, a technology that closes the aperture by providing a shielding member around the connector of the electronic control apparatus has been well known. Moreover, as for an electronic control apparatus that is configured with an upper lid and a lower lid, a division wall surrounding the connector is provided to the upper lid to prevent the foreign object and the like from reaching the electronic circuit board by keeping the foreign object and the like inside the division wall. Such a technology against a foreign object and the like has been well known.

However, the technology that provides the shielding member around the connector of the electronic control apparatus has increased manufacturing cost and work process. As for the technology that surrounds the connector by the division wall provided to the upper lid, since all outer circumference of the upper lid needs to touch all outer circumference of the lower lid, if the lids are slightly loose or if the lids are misaligned during production, the foreign object and the like enter from a portion connecting the upper lid with the lower lid due to looseness or misalignment.

### SUMMARY OF THE INVENTION

According to one aspect of the invention, an electronic control apparatus that electronically controls a controlled object includes: a case that includes a first aperture on a surface that faces in a first direction; a first electronic circuit board that slides into the case through the first aperture so as to be inserted into the case; a connector that is mounted on an end portion of the first electronic circuit board, the end portion being an end of the first electronic circuit board facing in the first direction, the connector having first and second oppositely facing sides, the first side of the connector having a terminal facing the first direction, the second side of the connector facing in a second direction opposite the first direction; and a lid that closes the first aperture, the lid having a second aperture through which the first side of the connector extends. The lid includes a covering wall that covers at least the second side of the connector that faces the second direction.

Thus, since the connector is covered by the covering wall, it is possible to prevent a foreign object from entering the case.

Moreover, according to another aspect of the invention, the covering wall includes a first wall surface that covers the second side of the connector, and second, third and fourth wall surfaces that respectively cover three additional sides of the connector that extend in three directions other than a direction in which the connector is in contact with the first electronic circuit board, out of four directions orthogonal to the second direction.

Thus, since the connector is entirely covered by the covering wall, it is possible to further prevent the foreign object from entering the case.

Therefore, an object of the invention is to provide a technology that effectively prevents a foreign object, dust, etc. from entering an electronic control apparatus from a surrounding area of a connector of the electronic control apparatus.

These and other objects, features, aspects and advantages of the invention will become more apparent from the following detailed description of the invention when taken in conjunction with the accompanying drawings.

### BRIEF DESCRIPTION OF THE DRAWINGS

FIG. 1 is a perspective view of an electronic control apparatus;

FIG. 2 is a perspective view of the electronic control apparatus;

FIG. 3 is a cross-sectional view of the electronic control apparatus;

FIG. 4 illustrates a move of a cover for the electronic control apparatus;

FIG. 5 illustrates a perspective view of an electronic control apparatus of a second embodiment;

FIG. 6 is a cross-sectional view of the electronic control apparatus of the second embodiment;

FIG. 7 illustrates a state before a cover abuts on a second electronic circuit board; and

FIG. 8 illustrates a state in which the cover abuts on the second electronic circuit board.

### DESCRIPTION OF THE EMBODIMENTS

An embodiment of the invention will be described below with reference to the drawings.

### 1. First Embodiment

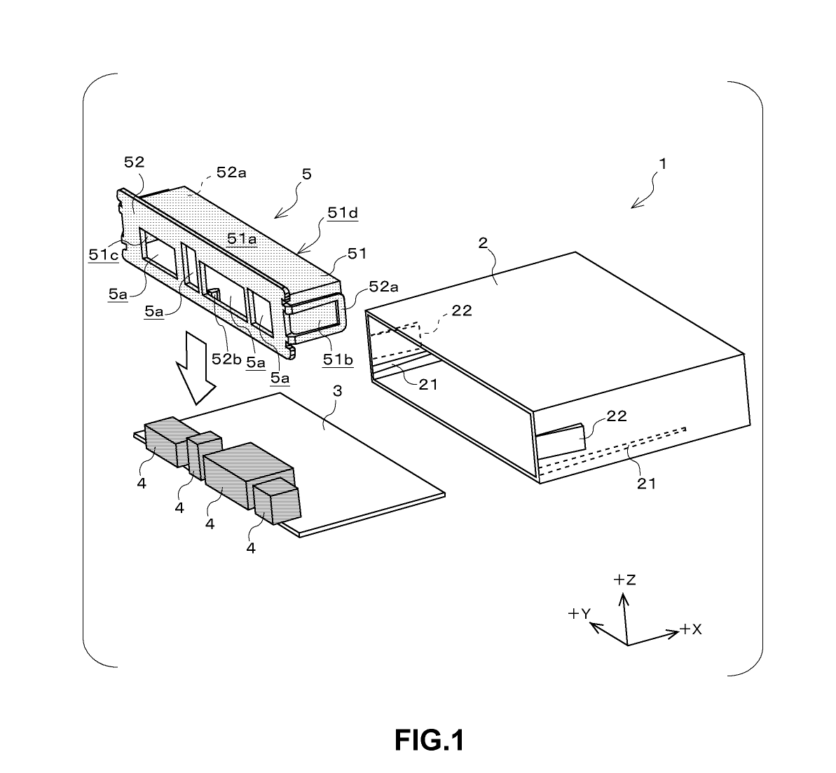

FIG. 1 is an exploded perspective view of an electronic control apparatus 1. The electronic control apparatus 1 is mounted in a vehicle, for example, a car, and electronically controls an object to be controlled (controlled object) in the vehicle. Some among examples of the controlled objects are an apparatus (remote engine starter) that remotely starts an engine of the vehicle and an apparatus that controls airbags. The electronic control apparatus 1 is mounted and fixed in the vehicle in a predetermined position of a fixed surface (body) of the vehicle with bolts, not illustrated. The electronic control apparatus 1 includes a case 2, an electronic circuit board 3, a connector 4 and a connector cover 5.

A direction and an orientation are indicated based on a three dimensional Cartesian coordinate system shown in FIG. 1 in the explanation below. The Cartesian coordinate system indicates approximate directions in a case where the electronic control apparatus 1 is mounted on the fixed surface. The Cartesian coordinate system is fixed relative to the electronic control apparatus 1 in the drawings. A +X direction represents a rear side of the electronic control apparatus 1 (viewed from a connector side). A +Y direction represents a left side of the electronic control apparatus 1 (viewed from the connector side). A +Z direction represents an upper side of the electronic control apparatus 1 (a side opposite to an approximate direction of gravitational force). A front-back direction, a horizontal direction and a vertical direction in the explanation below are according to the example in FIG. 1. A direction indicated with a mark “−” shows a direction opposite to the direction indicated with a mark “+.”

The case 2 is a substantially box-shaped container including an aperture to store the electronic circuit board 3. The aperture is formed on a −X side surface of the case 2. It is recommended that the case 2 should be made of resin, such as polypropylene, because polypropylene has a light weight and good waterproof performance. A guiding groove 21 is formed on each of left and right (+Y and −Y directions) inner surfaces of the case 2 to fix the electronic circuit board 3 in a predetermined position. Moreover, an engaging part 22 is formed on each of left and right (+Y and −Y directions) outer surfaces of the case 2 to be engaged with the connector cover 5. The case 2 functions as a box. The −X direction is a first direction in this embodiment.

The guiding grooves 21 guide the electronic circuit board 3 to an inside of the case 2. A vertical width of each guiding groove 21 near the aperture is formed greater than a thickness of the electronic circuit board 3. The vertical width of the guiding groove 21 becomes smaller as the guiding groove 21 progresses further rearward into the case 2. The vertical width of the guiding groove 21 is equal to or smaller than the thickness of the electronic circuit board 3 in a rearward end (+X side) of the guiding groove 21. The vertical width of the guiding groove 21 near the aperture is greater than the thickness of the electronic circuit board 3 so that the electronic circuit board 3 is easily inserted into the guiding grooves 21. Moreover, the vertical width of the guiding groove 21 becomes smaller as the guiding groove 21 progresses further rearward into the case 2 so that the electronic circuit board 3 is fixed to the guiding grooves 21.

The engaging parts 22 are members via which the case 2 is engaged with the connector cover 5. The engaging parts 22 are formed so as to have no projection height (a height projecting leftward and rightward from the case 2) near the aperture and to have higher projection height as the engaging parts 22 extend more rearward (+X side), to easily and firmly fit the connector cover 5 to the case 2.

The electronic circuit board 3 is a printed wiring board having a large number of ICs, resistors, capacitors and other electronic parts fixed on a surface of the printed wiring board and wired to one another by copper foil conductors and the like. The electronic circuit board 3 slides into the case (inward direction) along the guiding grooves 21 from the −X direction so as to be inserted into the case 2. The electronic circuit board 3 includes a notch (not illustrated) in a horizontal center of the electronic circuit board 3. The notch is a very small concave portion. The electronic circuit board 3 functions as a first electronic circuit board. The +X direction is a second direction in this embodiment.

The connector 4 is equipment that connects the electronic circuit board 3 to the controlled object that is controlled by the electronic control apparatus 1 via a cable. The connector 4 includes a terminal facing the −X direction and is installed on a −X-side end portion of a surface of the electronic circuit board 3. A surface of the connector 4 that is connected to the controlled object is not covered and faces outward from the electronic control apparatus 1.

The connector cover 5 is fixed to the electronic circuit board 3 and functions as a lid of the case 2 and also covers the connector 4. The connector cover 5 includes a cover wall 51, a cover 52, an engaging member 52a and a projection 52b. The connector cover 5 functions as a lid.

The cover wall 51 includes an upper covering wall 51a, a right side covering wall 51b, a left side covering wall 51c and a rear covering wall 51d to cover the connector 4. In other words, the upper covering wall 51a covers an upper side (+Z side) of the connector 4. The right side covering wall 51b covers a right side (−Y side) of the connector 4. The left side covering wall 51c covers a left side (+Y side) of the connector 4. The rear covering wall 51d covers a rear side (+X side) of the connector 4. Therefore, the connector 4 is entirely covered by the electronic circuit board 3 located on a lower side (−Z side) of the connector 4 and by the cover wall 51, except the side (−X side) not covered by the connector cover 5 and externally visible. In other words, the connector cover 5 covers the connector 4 in three directions (+Z, +Y and −Y directions) other than a direction (−Z direction) in which the connector 4 is in contact with the electronic circuit board 3, out of four directions (+Z, −Z, +Y and −Y directions) orthogonal to the +X direction. It is recommended that the connector cover 5 is made of resin, such as polypropylene, like the case 2, because polypropylene has a light weight and good waterproof performance and is bendable.

The cover 52 is the lid for the aperture of the case 2. The cover 52 has an aperture 5a through which a −X-side portion of the connector 4 extends. Since the portion of the connector 4 is uncovered and visible in the aperture 5a, the cover 52 functions as the lid that closes the aperture of the case 2. The aperture 5a of the cover 52 is slightly greater than the connector 4 to easily insert the connector 4 into the aperture 5a.

The engaging member 52a is a hook provided to each of left and right (+Y and −Y directions) surfaces outside the connector cover 5. The engaging member 52a is engaged with the engaging part 22 of the case 2 to fit the connector cover 5 to the case 2. In a case where the connector cover 5 is made of bendable resin, the engaging member 52a is flexibly deformed to be engaged with the engaging part 22 so that the engaging member 52a firmly fits the connector cover 5 to the case 2 by repulsive force generated by elastic deformation.

The projection 52b is a small projection projecting in the +X direction and is provided to a horizontal center inside the connector cover 5 so as to abut on the electronic circuit board 3. When the connector cover 5 is fixed to the electronic circuit board 3, the projection 52b abuts on the notch of the electronic circuit board 3 and functions as a positioning member for the connector cover 5 to the electronic circuit board 3. Moreover, since slightly projecting from the connector cover 5, the projection 52b presses the electronic circuit board 3 inward in the case 2 to prevent the electronic circuit board 3 from rattling in the case 2.

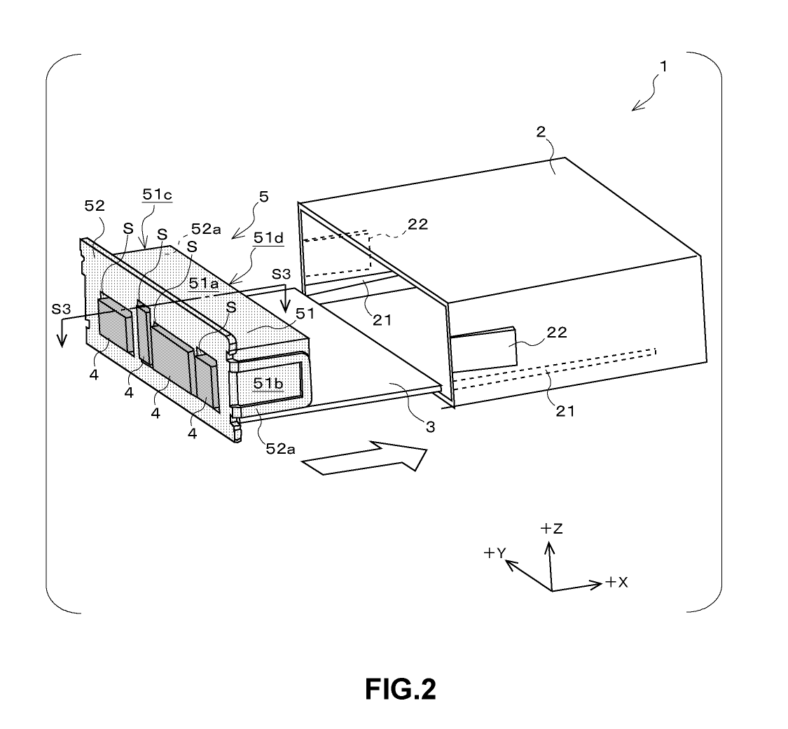

FIG. 2 illustrates the connector cover 5 fixed to the electronic circuit board 3. Once the connector cover 5 is fixed to the electronic circuit board 3, the electronic circuit board 3, the connector 4 and the connector cover 5 are inserted into the case 2 and functions as the electronic control apparatus 1.

When the connector cover 5 is fixed to the electronic circuit board 3, part of the connector 4 is uncovered and is visible in the aperture 5a of the connector cover 5, and a small opening S is generated between the connector cover 5 and the connector 4. As described above, the aperture 5a of the connector cover 5 is formed to be slightly greater than the connector 4. The opening S is a cause of a foreign object or dust entering the electronic control apparatus 1.

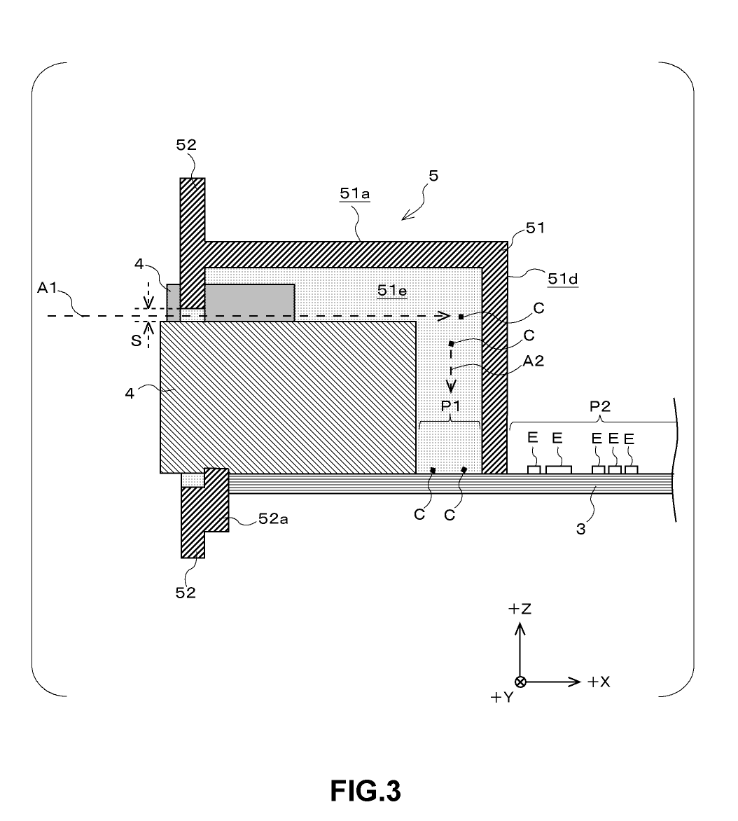

FIG. 3 is a cross-sectional view of the connector cover 5 fixed to the electronic circuit board 3 (viewed from a viewpoint S3 in FIG. 2) and illustrates entry pathways (A1 and A2) of a foreign object C to an internal space 51e in the connector cover 5. The foreign object C is minute metal debris, dust, etc. of 1 mm or smaller.

The foreign object C enters the internal space 51e of the connector cover 5 from the small opening S generated between the connector cover 5 and the connector 4 from an outside (the entry pathway A1).

The foreign object C that has entered the internal space 51e of the connector cover 5 is blocked by the rear covering wall 51d from moving further inward and falls onto a covered surface P1 that is a portion of the electronic circuit board 3 and that is covered by the connector cover 5 (the entry pathway A2).

Therefore, the foreign object C does not reach a non-covered surface P2 that is a portion of the electronic circuit board 3 and that is not covered by the connector cover 5. The foreign object C does not reach a non-covered surface P2 because the connector 4 is covered by the connector cover 5 having the cover wall 51. Thus, since an electronic device E and wiring are provided only on the non-covered surface P2, not on the covered surface P1, even if the foreign object C enters the internal space 51e from the opening S between the connector cover 5 and the connector 4, the foreign object C does not cause any problem to the electronic device E and the like.

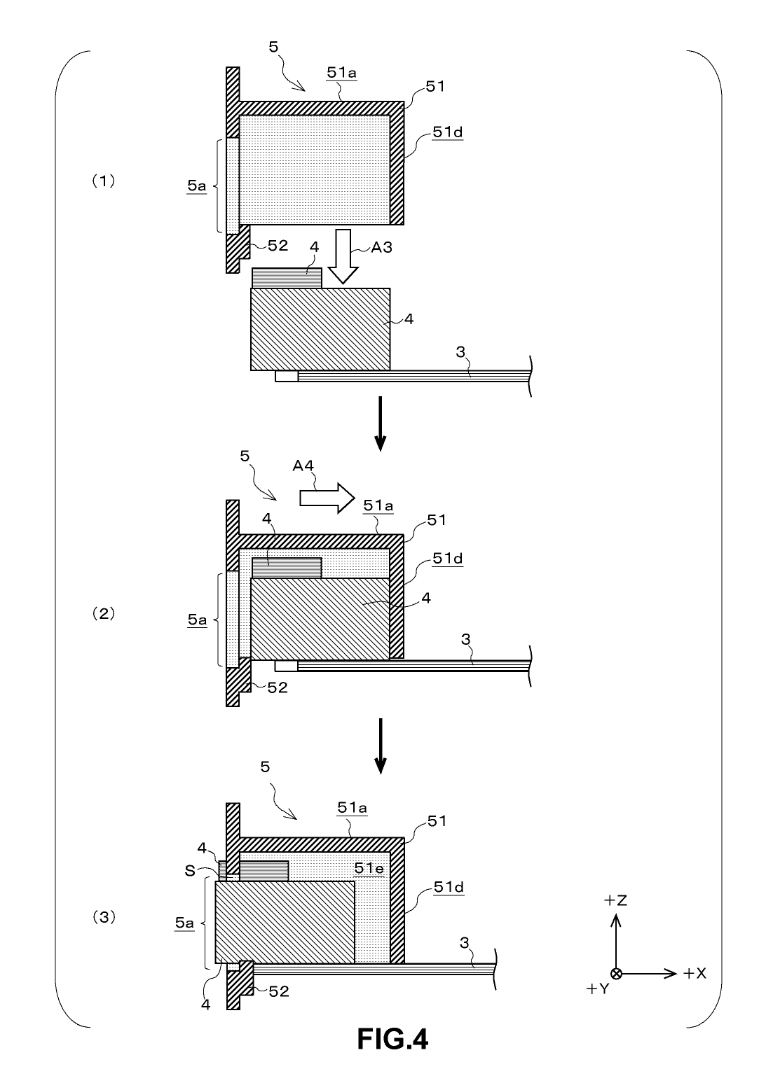

Drawings (1) to (3) of FIG. 4 illustrate a procedure of fixing the connector cover 5 to the electronic circuit board 3, and thus the connector 4 is covered by the connector cover 5.

The drawing (1) of FIG. 4 illustrates the connector cover 5 is held above the connector 4 fixed on the electronic circuit board 3.

In the drawing (2) of FIG. 4, the connector cover 5 is moved, from a state illustrated in the drawing (1) of FIG. 4, in a direction A3 (−Z direction) in which the connector 4 is located, and then a lower (−Z side) surface of the connector cover 5 reaches the electronic circuit board 3. The connector 4 is covered by the connector cover 5 in a state shown in the drawing (2) of FIG. 4.

In the drawing (3) of FIG. 4, the connector cover 5 is moved in a rearward direction A4 (+X direction) of the connector 4 from the state in the drawing (2) of FIG. 4, and then the connector 4 is inserted into the aperture 5a of the connector cover 5. In this state, the opening S is generated between the connector cover 5 and the connector 4. The connector cover 5 is fixed such that the lower (−Z side) surface contacts with the electronic circuit board 3. The connector cover 5 is moved in the rearward direction A4 (+X direction) of the connector 4 so that internal space 51e is generated between the connector 4 and the cover wall 51. The internal space 51e keeps inside the foreign object C that has entered the internal space 51e from the opening S between the connector cover 5 and the connector 4, to prevent the foreign object C from moving further rearward in the electronic control apparatus 1.

As described above, the electronic control apparatus 1 of the first embodiment includes the connector cover 5 that closes the aperture of the case 2 and that is formed so as to have the aperture 5a into which part of the connector 4 is inserted. The connector cover 5 includes the cover wall 51 that covers the connector 4 at least from the rear side (+X side).

Thus, since the connector 4 is covered by the cover wall 51, it is possible to prevent the foreign object C from moving inward (+X direction) in the case 2.

Moreover, in the electronic control apparatus 1 of the first embodiment, the cover wall 51 covers the connector 4 in the three directions (+Z, +Y and −Y directions) other than the direction (−Z direction) in which the cover wall 51 is in contact with the electronic circuit board 3, out of the four directions (+Z, −Z, +Y and −Y directions) of which the cover wall 51 is orthogonal to the +X direction.

Thus, since the cover wall 51 entirely covers the connector 4, it is possible to further prevent the foreign object C from moving inward in the case 2.

### 2. Second Embodiment

In the first embodiment, the electronic control apparatus 1 has one electronic circuit board 3. However, in a second embodiment, even if another electronic circuit board is added, an electronic control apparatus 1 prevents a foreign object from being attached to the added electronic circuit board, and the added electronic circuit board can be mounted without rattling. Thus, it is possible to increase an object to be controlled by the electronic control apparatus 1 or a controlling operation performed by the electronic control apparatus 1. For example, the electronic control apparatus 1 may include an electronic circuit board for controlling a remote engine starter system and an electronic circuit board for controlling airbags.

The second embodiment includes same elements as the elements in the first embodiment. Therefore, a difference from the first embodiment will be mainly described below. Moreover, the same elements as the elements in the first embodiment will be given same numerical references.

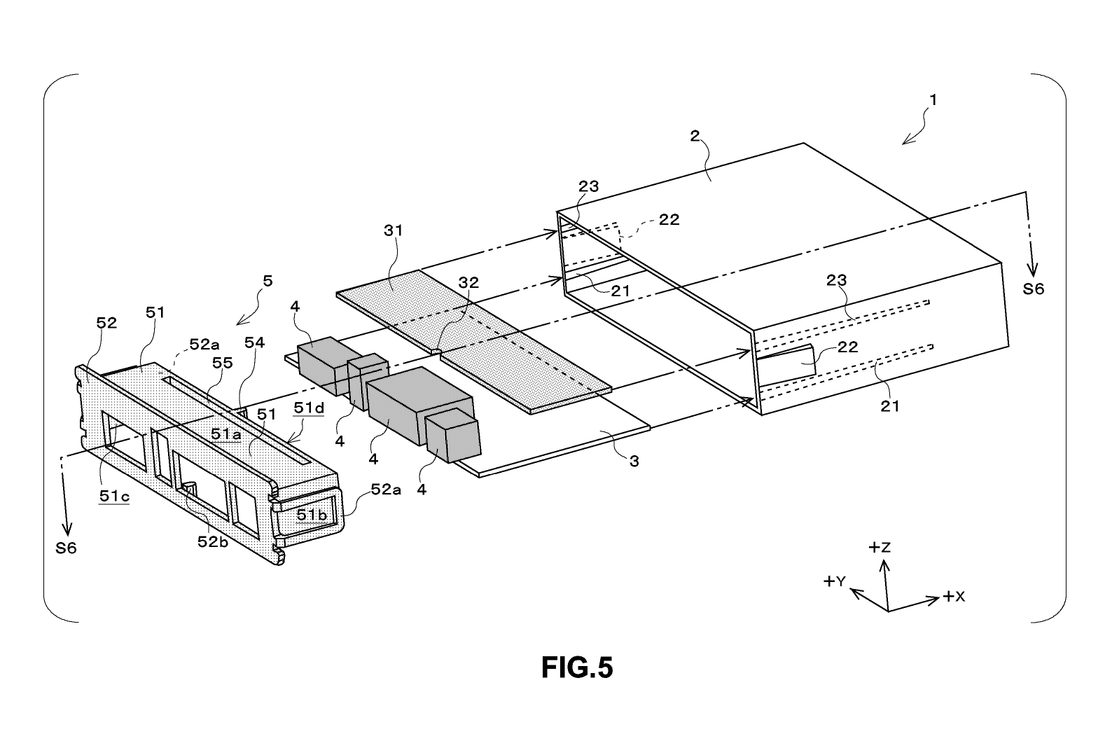

FIG. 5 illustrates an exploded perspective view of the electronic control apparatus 1 of the second embodiment. The electronic control apparatus 1 includes a second electronic circuit board 31 in addition to an electronic circuit board 3.

Being same as the electronic circuit board 3, the second electronic circuit board 31 is a printed wiring board having a large number of ICs, resistors, capacitors and other electronic parts fixed on a surface of the printed wiring board and wired to one another by copper foil conductors and the like. The second electronic circuit board 31 includes a second notch 32 in a horizontal center on a side (−X side) on which a connector cover 5 is provided when being stored in a case 2. The second notch 32 is a very small concave portion.

A guiding groove 23 is formed on each of left and right inner surfaces of the case 2 to fix the second electronic circuit board 31 in a predetermined position. Like the guiding grooves 21, the guiding grooves 23 guide the second electronic circuit board 31 to an inside of the case 2.

The connector cover 5 includes a second projection 54 and a slit 55.

The second projection 54 is a small projection projecting inward (+X side) and is provided to a horizontal center of a rear covering wall 51d of the connector cover 5 so as to abut on the second electronic circuit board 31. When the connector cover 5 is fixed to the electronic circuit board 3, the second projection 54 abuts on the second notch 32 of the second electronic circuit board 31 and functions as a positioning member for the connector cover 5 to the second electronic circuit board 31. Moreover, since slightly projecting from the connector cover 5, the second projection 54 presses the second electronic circuit board 31 inward in the case 2 (+X side), and prevents the second electronic circuit board 31 from rattling in the case 2. The second projection 54 functions as a projection part.

The slit 55 is a horizontally (+Y to −Y direction) long and narrow aperture provided to an upper covering wall 51a. Since the connector cover 5 includes the slit 55, a thickness of an upper (+Z side) portion of the rear covering wall 51d is reduced. Since the thickness of the upper (+Z side) portion of the rear covering wall 51d is reduced, when the second projection 54 abuts on and presses the second electronic circuit board 31, the upper portion of the rear covering wall 51d is distorted opposite (−X side) to the second electronic circuit board 31. The distortion generates an elastic force that presses the second electronic circuit board 31 rearward (+X side) via the second projection 54 in the case 2. The second electronic circuit board 31 is pressed rearward (+X side) in the case 2 so that the second electronic circuit board 31 is firmly stored in the case 2 and the second electronic circuit board 31 is prevented from rattling.

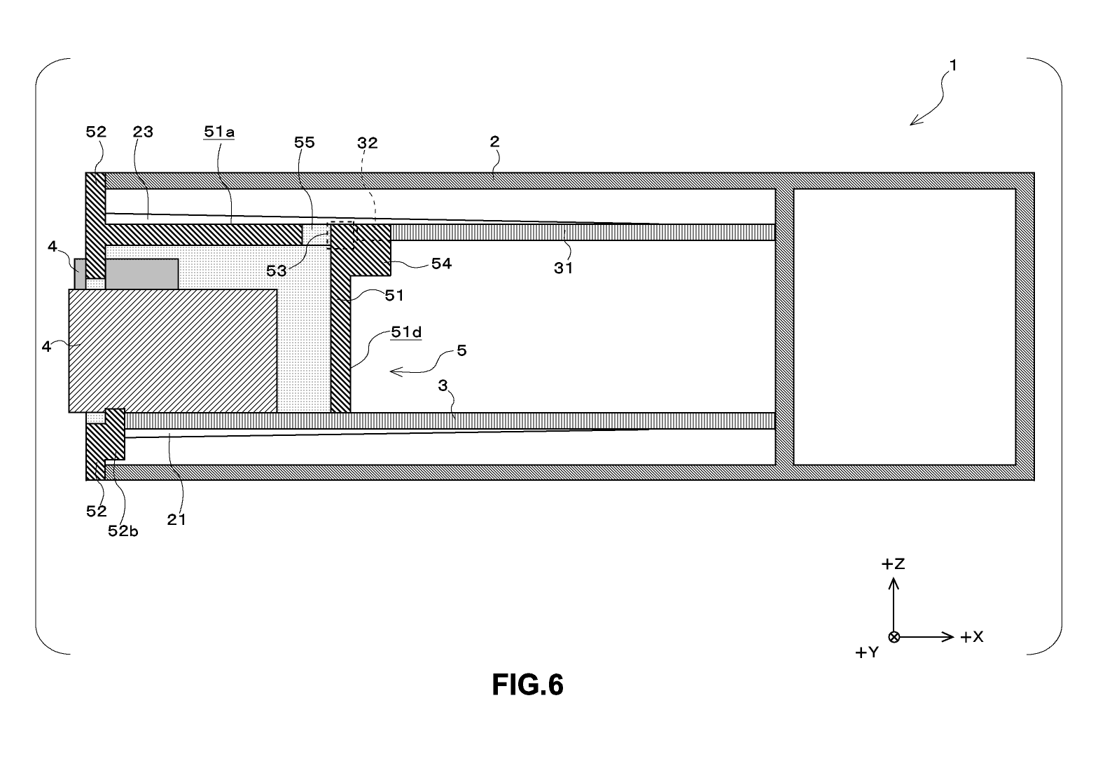

FIG. 6 is a cross-sectional view of the electronic control apparatus 1 storing the second electronic circuit board 31 (viewed from a viewpoint S6 in FIG. 5)

The second electronic circuit board 31 is inserted along the guiding grooves 23 into the case 2. As described above, when the second electronic circuit board 31 is inserted into the case 2, the second projection 54 of the connector cover 5 abuts on the second notch 32 of the second electronic circuit board 31. When abutting on the second notch 32 of the second electronic circuit board 31, the second projection 54 presses the second electronic circuit board 31 rearward (+X side) in the case 2 by a repulsive force of an engaging member 52a. When the second electronic circuit board 31 is pressed rearward (+X side) in the case 2, an upper portion 53 of the rear covering wall 51d is distorted opposite (−X side) to the second electronic circuit board 31 and thus the elastic force that presses back the second electronic circuit board 31 is generated. As described above, since the second electronic circuit board 31 is pressed rearward (+X side) in the case 2, the second electronic circuit board 31 is stored in the case 2 and the second electronic circuit board 31 is prevented from rattling.

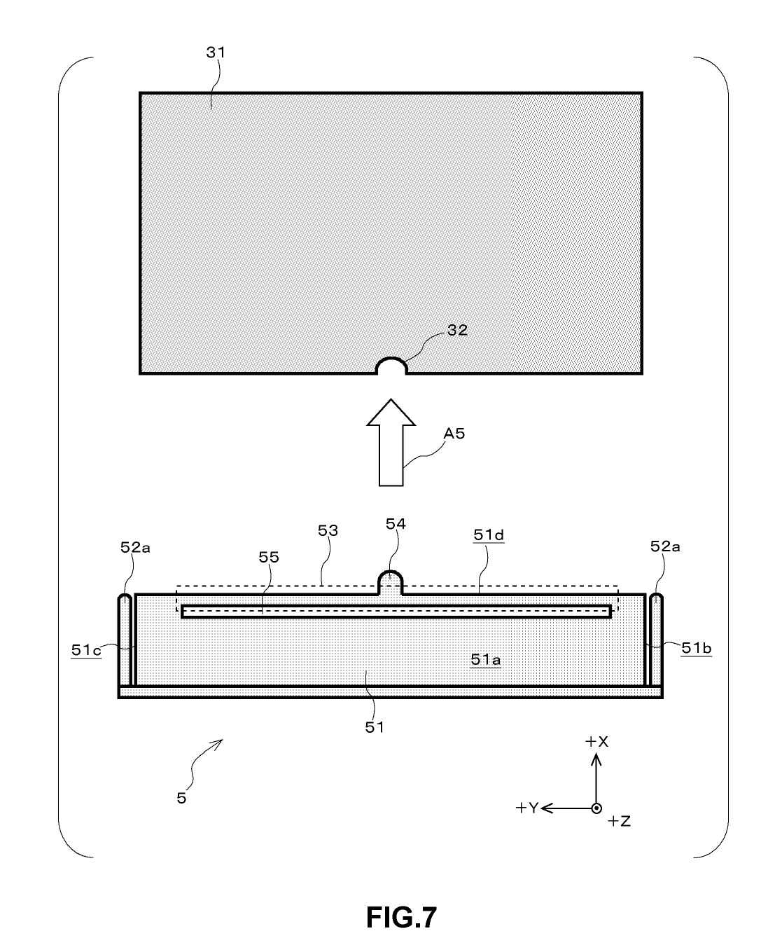

FIG. 7 illustrates a state before the second projection 54 of the connector cover 5 abuts on the second notch 32 of the second electronic circuit board 31.

In this state, the connector cover 5 is moved in a direction (a direction A5) toward the second electronic circuit board 31 (+X side) to cause the second projection 54 of the connector cover 5 to abut on the second notch 32 of the second electronic circuit board 31. At this time point, the upper portion 53 (+Z side portion) of the rear covering wall 51d is not distorted.

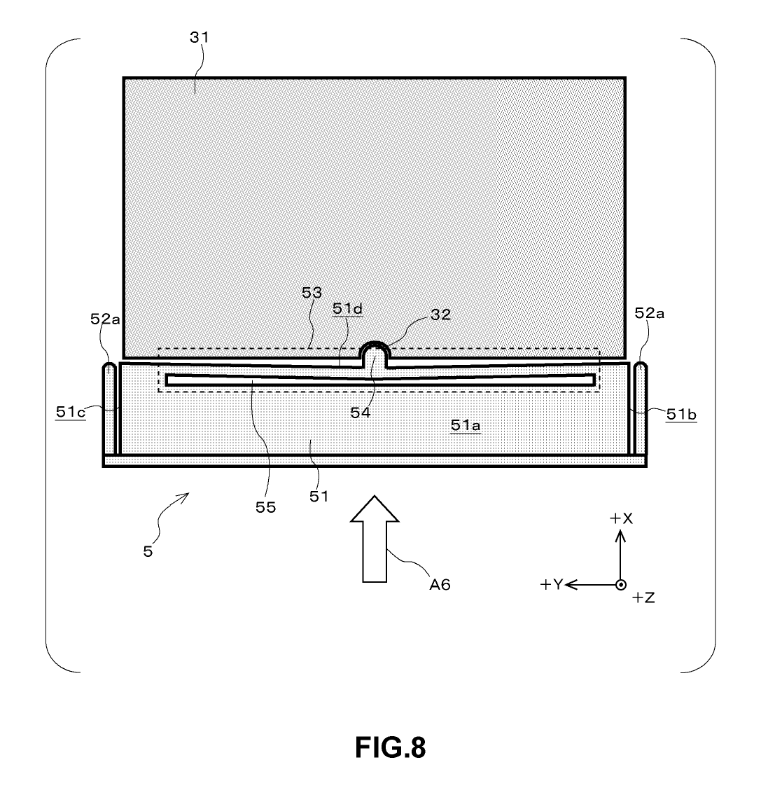

FIG. 8 illustrates in a state in which distortion of the upper portion 53 (+Z side portion) of the rear covering wall 51d is caused when the second projection 54 of the connector cover 5 abuts on the second notch 32 of the second electronic circuit board 31. The distortion presses the second electronic circuit board 31 rearward (+X side) in a direction A6 in the case 2 via the second projection 54 of the connector cover 5, and thus the second electronic circuit board 31 is prevented from rattling.

As described above, in the electronic control apparatus 1 of the second embodiment, the slit 55 provided to the rear covering wall 51d generates the elastic force. The second electronic circuit board 31 is secured by the elastic force. Thus, the electronic control apparatus 1 is configured to store the second electronic circuit board 31 without rattling in the case 2, in addition to the electronic circuit board 3.

### 3. Modifications

The embodiments of the invention are described above. However, the invention is not limited to the foregoing embodiments and various modifications are possible. Some examples of those modifications will be described below. Any of the foregoing embodiments and the modifications below may be arbitrarily combined with one another.

In the foregoing embodiments, it is recommended that the case 2 and the connector cover 5 should be made of polypropylene. However, the case 2 may not be made of polypropylene. The case 2 may be made by metal die casting, using, for example, aluminum, more specifically, ADC12 because ADC12 has high hardness and good plastic property and is relatively easily available.

Moreover, the connector cover 5 also may not be made of polypropylene but may be made of another plastic material. One example of the plastic material is a polymer alloy (PC/ABS alloy) of polycarbonate (PC) and ABS resin. The PC/ABS alloy has good plastic property, impact resistance, heat resistance and fire retardancy.

In the foregoing embodiments, the electronic control apparatus 1 is mounted on a vehicle, such as a car. However, the electronic control apparatus 1 may not be mounted on a vehicle. The electronic control apparatus 1 may be installed in a place in which a foreign object and/or dust may be generated. Therefore, the electronic control apparatus 1 may be an electronic control apparatus that is provided to an exterior wall of a building. One example of the electronic control apparatus is an intercommunication system.

In the foregoing embodiment, two electronic circuit boards are mounted in the electronic control apparatus 1. However, a number of the electronic circuit boards may not be two boards, but three boards may be mounted. In this case, the electronic control apparatus 1 may be formed larger in height (expanded in +Z to −Z direction).

While the invention has been shown and described in detail, the foregoing description is in all aspects illustrative and not restrictive. It is therefore understood that numerous other modifications and variations can be devised without departing from the scope of the invention.

What is claimed is:

1. An electronic control apparatus that electronically controls a controlled object, the electronic control apparatus comprising:
a case that includes a first aperture on a surface that faces in a first direction;
a first electronic circuit board that slides into the case through the first aperture so as to be inserted into the case;
a connector that is mounted on an end portion of the first electronic circuit board, the end portion being an end of the first electronic circuit board facing in the first direction, the connector having first and second oppositely facing sides, the first side of the connector having a terminal facing the first direction, the second side of the connector facing in a second direction opposite the first direction; and
a lid that closes the first aperture, the lid having a second aperture through which the first side of the connector extends, wherein
the lid includes a covering wall that covers at least the second side of the connector that faces the second direction.

2. The electronic control apparatus according to claim 1, wherein
the covering wall includes a first wall surface that covers the second side of the connector, and second, third and fourth wall surfaces that respectively cover three additional sides of the connector that extend in three directions other than a direction in which the connector is in contact with the first electronic circuit board, out of four directions orthogonal to the second direction.

3. The electronic control apparatus according to claim 1, further comprising:
a projection that projects from the covering wall in the second direction;
a slit in the covering wall, the slit extending along a direction orthogonal to the second direction, the slit providing an elastic force to the projection in the second direction when the projection is pressed in the first direction; and
a second electronic circuit board that abuts on the projection and is secured within the case by the elastic force.

4. The electronic control apparatus according to claim 1, further comprising:
guiding grooves provided in inner side surfaces of the case and along which the first electronic circuit board slides into the case through the first aperture.

5. The electronic control apparatus according to claim 4, wherein
a width of each of the guiding grooves decreases as each groove progresses further rearward into the case.

6. A method for producing an electronic control apparatus that includes a case having a first aperture on a surface that faces in a first direction, the method comprising:
(a) sliding a first electronic circuit board into the case through the first aperture;
(b) mounting a connector on an end portion of the first electronic circuit board, the end portion being an end of the first electronic circuit board facing in the first direction, the connector having first and second oppositely facing sides, the first side of the connector having a terminal facing the first direction; the second side of the connector facing in a second direction opposite the first direction; and
(c) closing the first aperture of the case with a lid having a second aperture through which the first side of the connector extends, wherein
the lid includes a covering wall that covers at least the second side of the connector that faces the second direction.

7. The method according to claim 6, wherein
the covering wall includes a first wall surface that covers the second side of the connector, and second, third and fourth wall surfaces that respectively cover three additional sides of the connector that extend in three directions other than a direction in which the connector is in contact with the first electronic circuit board, out of four directions orthogonal to the second direction.

8. The method according to claim 6, wherein
a projection projects from the covering wall in the second direction;
a slit is provided in the covering wall, the slit extending along a direction orthogonal to the second direction, the slit providing an elastic force to the projection in the second direction when the projection is pressed in the first direction; and
a second electronic circuit board abuts on the projection and is secured by the elastic force.

9. The method according to claim 6, wherein
guiding grooves are provided in inner side surfaces of the case and along which the first electronic circuit board slides into the case through the first aperture.

10. The method according to claim 9, wherein
a width of each of the guiding grooves decreases as each groove progresses further rearward into the case.
